(19) United States
(12) Patent Application Publication
(10) Pub. No.: US 2012/0305745 A1
(43) Pub. Date: Dec. 6, 2012

(54) FAN MOUNTING APPARATUS FOR AN ELECTRONIC DEVICE

(75) Inventors: Yun-Lung CHEN, Tu-Cheng (TW); Zhi-Qiang LI, Wuhan City (CN); Mao-Lin XU, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/367,417

(22) Filed: Feb. 7, 2012

(30) Foreign Application Priority Data
May 31, 2011 (CN) 201110143652.7

(51) Int. Cl. H05K 7/20

(52) U.S. Cl. 248/672

(57) ABSTRACT

A mounting apparatus for a fan, configured for securing the fan, includes a plate. The plate further includes a main body. The main body defines a ventilation area corresponding to the fan. At least two latching pieces and at least one protrusion extend from main body. The at least two latching pieces and the at least one protrusion are around the ventilation are. The at least two latching pieces is engaged with two opposite sides of the mounting board for preventing the fan from moving a first direction, a second direction opposite, and a third direction substantially perpendicular to the main body; and the at least one protrusion abuts the mounting board to prevent the fan from rotating in a fourth direction which the mounting board is disengaged from the at least two latching pieces.

### CROSS-REFERENCE TO RELATED APPLICATIONS

Relevant subject matter is disclosed in U.S. patent applications entitled “Fan mounting apparatus for heat dissipation”, Attorney Docket Number US39255, U.S. application Ser. No. 13/327,895, Filed on 2011 Dec. 16.

### BACKGROUND

1. Technical Field

The present disclosure relates to fan mounting apparatuses, particularly to a fan mounting apparatus which can conveniently and firmly secure a fan to a computer enclosure.

2. Description of Related Art

Computers generate a large amount of heat from electrical components. A fan is often used as a conventional means to dissipate the heat from the computer. Typically, the fan is mounted to a computer case through a plurality of screws. However, such a mounting configuration of the fan may be inconvenient for a user.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus and a fan.

FIG. 2 is a partial front view of the mounting apparatus of FIG. 1.

FIG. 3 is an enlarged view of circled portion III of FIG. 1.

FIG. 4 is an assembled view of the mounting apparatus and the fan of FIG. 1.

FIG. 5 is similar to FIG. 4, but the fan is rotated to a secure state.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

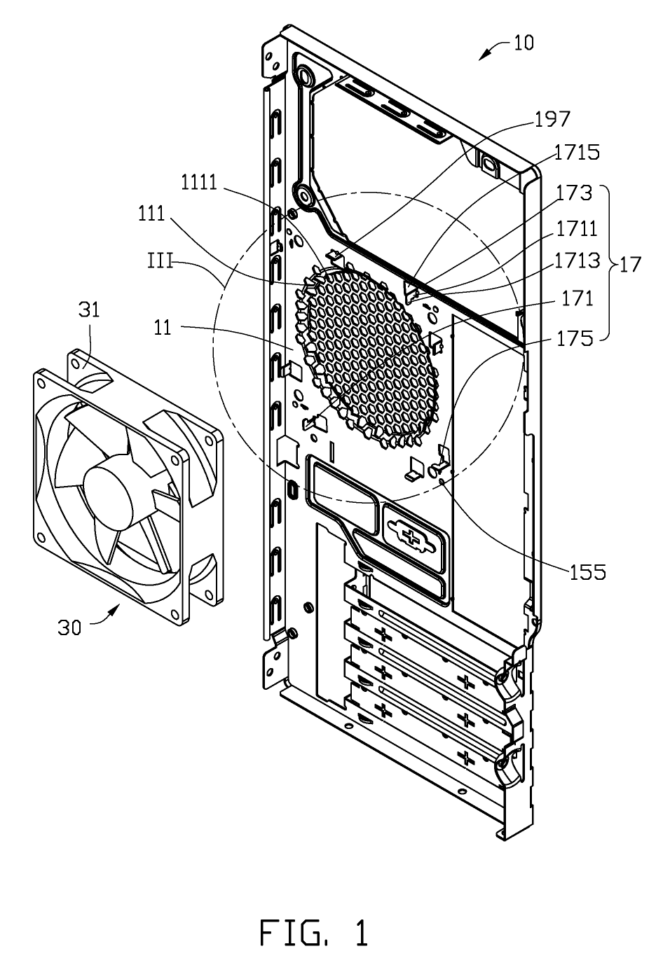

Referring to FIG. 1, a mounting apparatus in accordance with an embodiment comprises a plate 10. The mounting apparatus is used to mount a fan 30 on the plate 10. In one embodiment, the plate 10 may be a rear wall. The fan 30 comprises a mounting board 31.

The plate 10 comprises a main body 11 and a sidewall 13 located on the main body 11. In one embodiment, the sidewall 13 is substantially perpendicular to the main body 11.

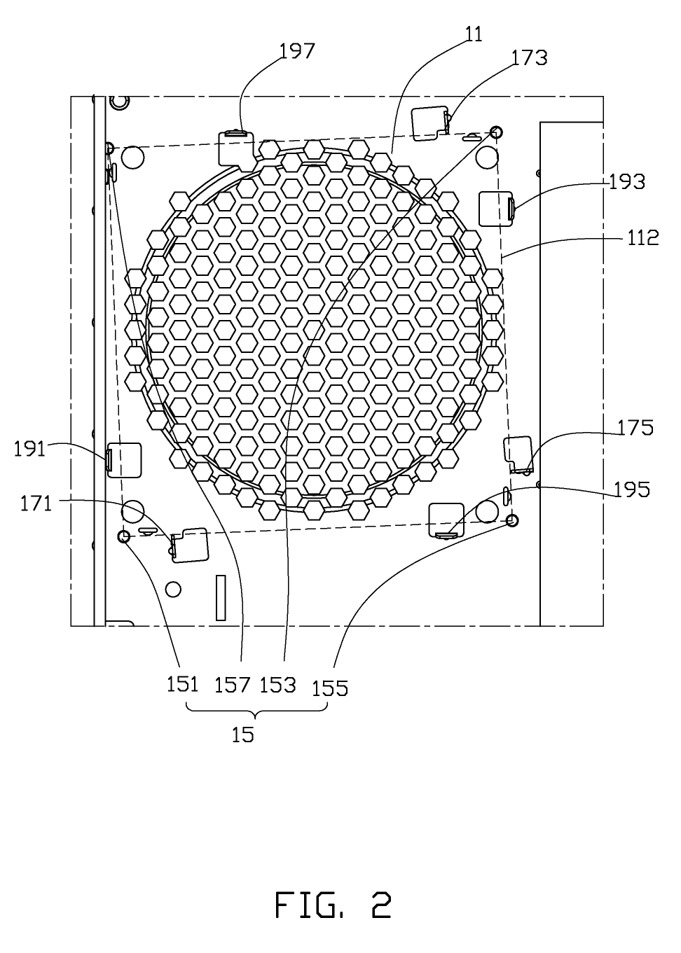

Referring to FIG. 2, the main body 11 defines a plurality of vents 1111 to form a substantially circular ventilation area 111 for airflow through the main body 11. In one embodiment, a rectangle 112 may be defined around the ventilation area 111. Four protrusions 15 are located on the main body 11. In on embodiment, the four protrusions 15 comprise a first protrusion 151, a second protrusion 153, a third protrusion 155, and a fourth protrusion 157. Each of the four protrusions 15 are arranged at the four corners of the rectangle 112.

Three latching pieces 17 extend from the main body 11. Each of the three latching pieces 17 comprises a connecting portion 1711 and an engaging portion 1713 substantially perpendicular to the connecting portion 1171. In one embodiment, the three latching pieces 17 comprise a first latching piece 171, a second latching piece 173 and a third latching piece 175. Three openings 1715 are defined in the main body 11. Each of the three latching pieces 17 has the same configuration and extends from an edge of each of the three openings 1715. In one embodiment, the first latching piece 171 is substantially parallel with the second latching piece 173, and substantially perpendicular to the third latching piece 175; an acute angle is defined between the sidewall 13 and a plane with a first latching piece 171; and an acute angle is defined between the sidewall 13 and a line of connecting the first latching piece 171 with the second latching piece 173.

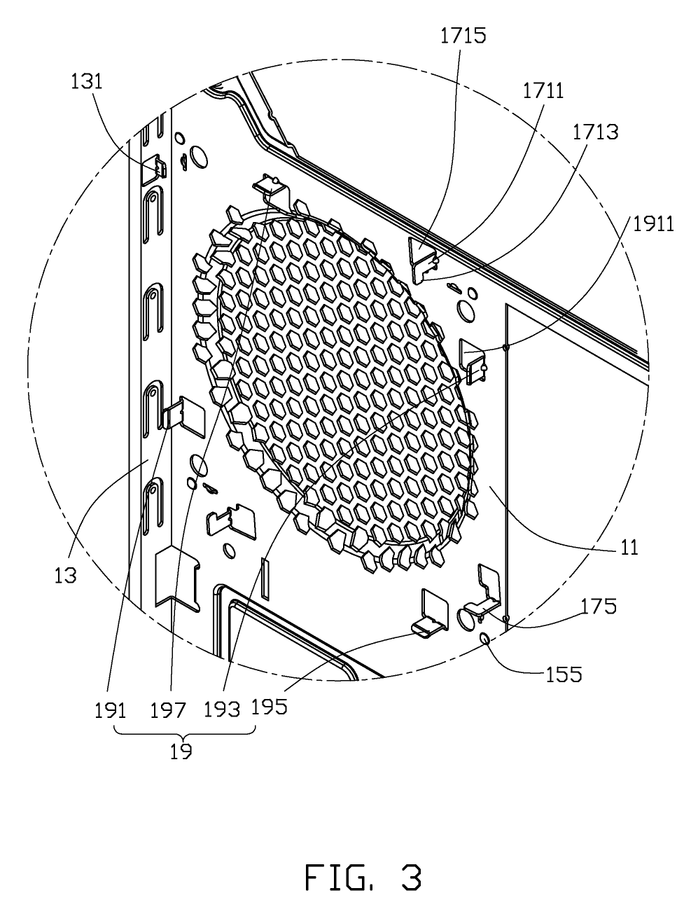

Referring to FIG. 3, four stopper pieces 19 are located on the main body 11. In one embodiment, the four stopper pieces 19 comprise a first stopper piece 191, a second stopper piece 193, a third stopper piece 195 and a fourth stopper piece 197. Each of the four stopper pieces 19 is substantially placed on an edge of the rectangle 112, Four through holes 1911 are defined on the main body 11. Each of the four stopper pieces 19 extends from an edge of each of the four through holes 1911, and is substantially perpendicular to the main body 11. In one embodiment, the first stopper piece 191 is substantially parallel to the second stopper piece 193, and substantially perpendicular to the third stopper piece 195 and the fourth stopper piece 197; the third stopper piece 195 is substantially parallel with the fourth stopper piece 197.

A limiting portion 131 is placed on the sidewall 13, and extends from inside of the sidewall 13. In one embodiment, the limiting portion 131 is substantially perpendicular to the sidewall 13; the first protrusion 151 is located between the first latching piece 171 and the first stopper piece 191; the second protrusion 153 is located between the second latching piece 173 and the second stopper piece 193; the third protrusion 155 is located between the third latching piece 175 and the third stopper piece 195; the fourth protrusion 157 is located between the limiting portion 131 and the fourth stopper piece 197.

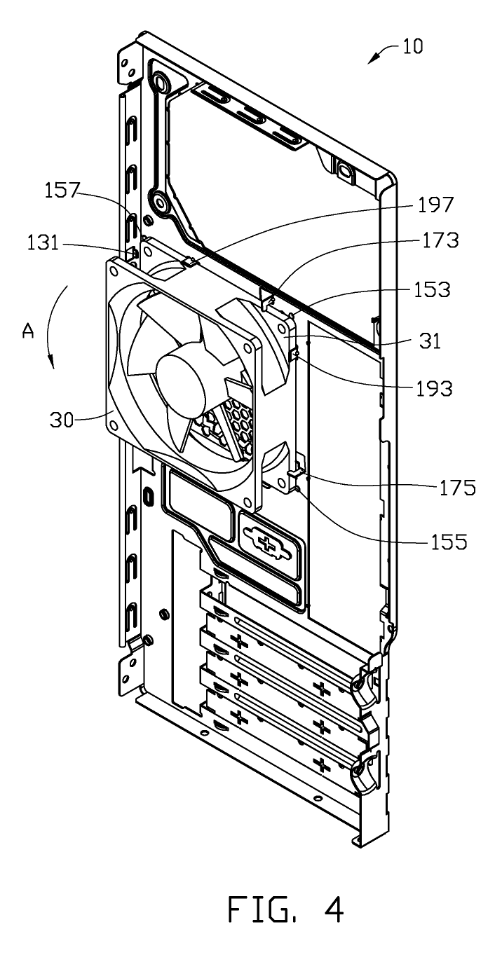

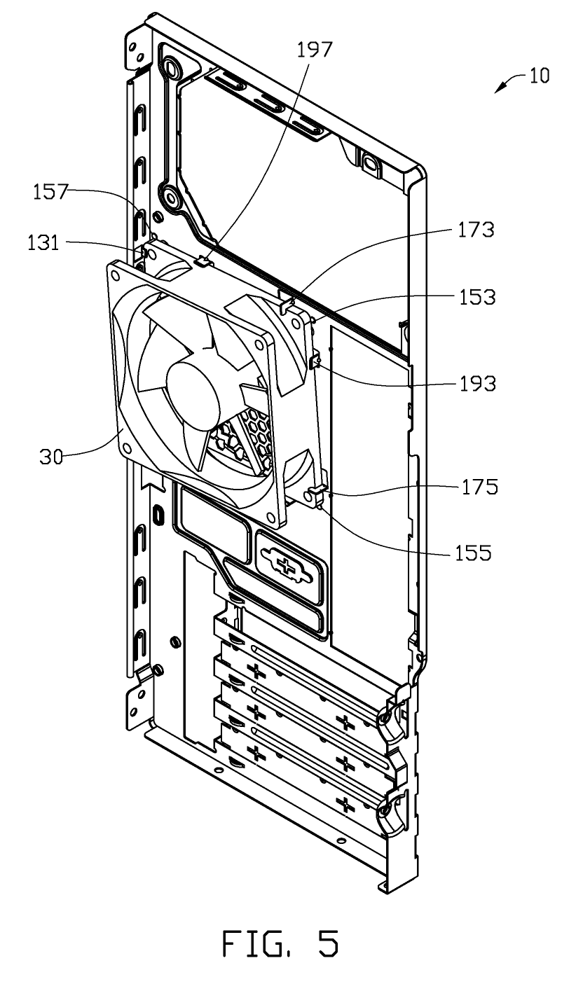

Referring to FIGS. 4 and 5, in assembly, the fan 30 is aligned with the ventilation area 111 to be received in the four stopper pieces 19. The first stopper piece 191 and the second stopper piece 193 abut a second opposite sides of the mounting board 31, the third stopper piece 195 and the fourth stopper portion 197 abut a first opposite sides of the mounting board 31; the first protrusion 151 and the second protrusion 153 abut the first opposite sides of the mounting board 31 The third protrusion 155 and the fourth protrusion 157 abut the second opposite sides of the mounting board 31. The fan 30 is rotated along direction A until the first latching piece 171 and the second latching piece 173 are engaged with the first opposite sides of the mounting board 31, the third latching piece 175 and the limiting portion 131 are engaged with the second opposite sides of the mounting board 31, and the first protrusion 151 and the second protrusion 153 abut the second opposite sides of the mounting board 31, the third protrusion 155 and the fourth protrusion 157 abut the first opposite sides of the mounting board 31. Therefore, the connecting portion 1711 of the three latching pieces 17 can prevent the fan 30 from moving in a first direction and a second direction opposite to the first direction. The engaging portion 1713 of the three latching pieces 17 and the limiting portion 131 can prevent the fan 30 from moving in a third direction which is substantially perpendicular to the main body 11. The four protrusions 15 prevent the fan 30 from rotating in a plane which is parallel with the main body 11 to the mounting board 31 disengaged from the three latching pieces 17 and the limiting portion 131. Thus, the fan 30 is in a first position which is mounted to the plate 10.

To disassemble the fan mounting apparatus, the fan 30 is rotated in a direction opposite to the direction A, until the fan 30 is disengaged from the engaging portion 1713 of the three latching pieces 17 and the limiting portion 131. Thus, the fan 30 is in a second position, the four stopper pieces 19 abut each of four edges of the mounting board 31. Therefore, the fan 30 can be detached from the plate 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A fan mounting apparatus comprising:
a plate comprising a main body, a first latching piece, a second latching piece substantially parallel with the first latching piece and at a least one protrusion protruding from the main body, the main body defining a ventilation area corresponding to the fan, the first latching piece, the second latching piece and the at least one protrusion being located around the ventilation area;
wherein the first latching piece and the second latching piece are engaged with two opposite sides of a mounting board of the fan; the first latching piece and the second latching piece is configured to prevent the fan from moving relative to the main body linearly along a first direction, a second direction opposite to the first direction, and a third direction substantially perpendicular to the main body; the at least one protrusion abuts the mounting board to prevent the fan from rotating in a plane parallel with the main body.

2. The fan mounting apparatus of claim 1, wherein each of the first latching piece and the second latching piece comprises a connecting portion connected to the main body, and an engaging portion substantially perpendicular to the connecting portion.

3. The fan mounting apparatus of claim 1, wherein the plate further comprises a sidewall connected to the main body, an acute angle is defined between the sidewall and a plane containing the first latching piece; and an acute angle is defined between the sidewall and a line connecting the first latching piece and the second latching piece.

4. The fan mounting apparatus of claim 3, wherein a third latching piece extends from the main body; each of the first latching piece, the second latching piece is substantially perpendicular to the third latching piece.

5. The fan mounting apparatus of claim 4, wherein the main body comprises three openings; each of the first latching piece, the second latching piece, and the third latching piece extends from each of the three openings.

6. The fan mounting apparatus of claim 5, wherein a limiting portion extends from the sidewall; four stopper pieces are located on the main body; the mounting board comprises four sides; the fan is configured to be rotated relative to the plate between a first position and a second position; when the fan is in the first position, the first latching piece and the second latching piece are engaged with first two opposite sides of the mounting board, the third latching piece and the limiting portion are engaged with second two opposite sides of the mounting board; when the fan in the second position, each of the four stopper portions abuts each of the four sides of the mounting board.

7. The fan mounting apparatus of claim 6, wherein the at least one protrusion comprise a first protrusion, a second protrusion, a third protrusion and a fourth protrusion, a rectangle is defined outside of the ventilation area; each of the first protrusion, the second protrusion, the third protrusion and the fourth protrusion is arranged at each corner of the rectangle.

8. The fan mounting apparatus of claim 7, wherein the four stopper pieces comprise a first stopper piece substantially parallel to a second stopper piece, a third stopper piece substantially parallel to a fourth stopper piece; the first stopper piece is substantially perpendicular to both the third stopper piece and the fourth stopper piece.

9. The fan mounting apparatus of claim 8, wherein the first protrusion is located between the first latching piece and the first stopper piece, the second protrusion is located between the second latching piece and the second stopper piece, the third protrusion is located between the third latching piece and the third stopper piece, and the fourth protrusion is located between the fourth stopper piece and the limiting portion of the sidewall.

10. The mounting apparatus of claim 9, wherein when the fan is in the first position, the first protrusion and the second protrusion abut the second two opposite sides of the mounting board, and the third protrusion and the fourth protrusion abut the first two opposite sides of the mounting board; when the fan is the second position, the first protrusion and the second protrusion abut the first two opposite sides of the mounting board, and the third protrusion and the fourth protrusion abut the second two opposite sides of the mounting board.

11. A fan mounting apparatus comprising:
a plate comprising a main body, at least two latching pieces, at least one protrusion and at least two stopper pieces extending from main body, the main body defining a ventilation area corresponding to the fan; wherein the at least two latching pieces, the at least one protrusion and the at least two stopper pieces are located around the ventilation area; and
wherein the fan is rotated between a first position and a second position; when the fan is in the first position, the at least two latching pieces engaged with first two opposite sides of a mounting board of the fan, and the at least one protrusion abuts the mounting board to prevent the mounting board from disengaging from the at least two latching pieces; when the fan is in the second position, the at least two stopper pieces abut second two opposite sides of the mounting board.

12. The fan mounting apparatus of claim 11, wherein each of the at least two latching pieces is substantially perpendicular to the main body.

13. The fan mounting apparatus of claim 11, wherein each of the at least two latching pieces comprises a connecting portion connected to the main body and an engaging portion connected to the connecting portion; and the engaging portion is substantially perpendicular to the connecting portion.

14. The fan mounting apparatus of claim 11, wherein the at least two latching piece comprise a first latching piece, a second latching piece and a third latching piece, the first latching piece is substantially parallel with the second latching piece, and the first latching piece is substantially perpendicular to the third latching piece.

15. The fan mounting apparatus of claim 14, wherein the main body defines three openings; each of the first latching piece, the second latching piece and the third latching piece extends from each of the three openings.

16. The fan mounting apparatus of claim 15, wherein the plate further comprises a sidewall connected to the main body, a limiting portion extends from the sidewall; when the fan in the first position, each of the first latching piece and the second latching piece is engaged with each of the first two opposite sides of the mounting board, each of the third latching piece and the limiting portion is engaged with each of the second two opposite sides of the mounting board.

17. The fan mounting apparatus of claim 16, wherein the at least two stopper pieces comprise a first stopper piece substantially parallel to a second stopper piece, a third stopper piece substantially parallel to a fourth stopper piece; the first piece is substantially perpendicular to both the third stopper piece and the fourth stopper piece.

18. The fan mounting apparatus of claim 17, wherein when the fan is in the second position, the first stopper piece and the second stopper piece abut the second opposite two sides of the mounting board, the third stopper piece and the fourth stopper piece are engaged with the first opposite two sides of the mounting board.

19. The fan mounting apparatus of claim 18, wherein the at least one protrusion comprise a first protrusion, a second protrusion, a third protrusion and a fourth protrusion, a rectangle is defined outside of the ventilation area; each of the first protrusion, the second protrusion, the third protrusion and the fourth protrusion is arranged at each corner of the rectangle.

20. The fan mounting apparatus of claim 19, wherein the first protrusion is located between the first latching piece and the first stopper piece, the second protrusion is located between the second latching piece and the second stopper piece, the third protrusion is located between the third latching piece and the third stopper piece, and the fourth protrusion is located between the fourth stopper piece and the limiting portion of the sidewall.
